(19) United States
(12) Patent Application Publication
(10) Pub. No.: US 2024/0421188 A1
(43) Pub. Date: Dec. 19, 2024

(54) SEMICONDUCTOR DEVICE AND METHOD FOR FABRICATING THE SAME

(71) Applicant: SAMSUNG ELECTRONICS CO., LTD., SUWON-SI (KR)

(72) Inventors: HYO KYOUNG KIM, Suwon-si (KR); KI WON CHO, Suwon-si (KR); DONG MIN SIM, Suwon-si (KR); SEOK WON YOON, Suwon-si (KR); CHUN HYUNG CHUNG, Suwon-si (KR)

(21) Appl. No.: 18/582,847

(22) Filed: Feb. 21, 2024

(30) Foreign Application Priority Data
Jun. 13, 2023 (KR) 10-2023-0075427

(51) Int. Cl. H01L 29/06; H01L 29/423; H01L 29/66; H01L 29/775; H01L 29/786; H10B 12/00

(52) U.S. Cl. CPC H01L 29/0673; H01L 29/42392; H01L 29/66439; H01L 29/775; H01L 29/78696; H10B 12/05; H10B 12/33; H10B 12/482; H10B 12/485; H10B 12/50

(57) ABSTRACT

Provided is a semiconductor device. The semiconductor device includes a substrate including an element isolation layer defining a plurality of active areas, and a plurality of gate structures intersecting the active areas. Each of the gate structures includes a gate insulating layer including a first region containing a first material and a second region containing a second material different from the first material on the active area, and a gate electrode layer on the gate insulating layer. A concentration of the second material in the first region is less than a concentration of the second material in the second region, and a thickness of the first region is less than a thickness of the second region.

### CROSS-REFERENCE TO RELATED APPLICATION

This application claims priority and all the benefits accruing therefrom under 35 U.S.C. 119 from Korean Patent Application No. 10-2023-0075427 filed on Jun. 13, 2023 in the Korean Intellectual Property Office, the contents of which in its entirety are herein incorporated by reference.

### BACKGROUND

### 1. Technical Field

The present disclosure relates to a semiconductor device and a method for fabricating the same.

### 2. Description of the Related Art

As semiconductor elements become increasingly integrated, there is an increasing need to secure operational characteristics of transistors despite the reduction in size of the transistors and the sizes of active areas in which the transistors are integrated.

A gate insulating layer of the transistor may be formed of an oxide layer obtained by performing an oxidation process on an active area of a semiconductor substrate, such as a silicon substrate. During the oxidation process, silicon in the active area may be oxidized, where the silicon (Si) in an active area is changed chemically.

Such Si loss or silicon oxidation phenomenon reduces the current that may flow through the transistor, and thus may be a factor in deteriorating the operating characteristics of the transistor.

### SUMMARY

Aspects of the present disclosure provide a semiconductor device capable of suppressing loss or oxidation of an active area of a transistor.

Aspects of the present disclosure also provide a method for fabricating a semiconductor device capable of suppressing loss or oxidation of an active area of a transistor.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising: a substrate comprising an element isolation layer defining a plurality of active areas; and a plurality of gate structures intersecting the plurality of active areas, wherein each of the plurality of gate structures comprises: a gate insulating layer comprising a first region containing a first material and a second region containing a second material different from the first material on the active area; and a gate electrode layer on the gate insulating layer, wherein a concentration of the second material in the first region is less than a concentration of the second material in the second region, and a thickness of the gate insulating layer in the first region is less than the thickness of the gate insulating layer in the second region.

According to another aspect of the present disclosure, there is provided a semiconductor device comprising: a substrate comprising an element isolation layer defining a cell region and a peripheral region around the cell region, and defining first active areas; and cell gate structures formed in a first trench on the substrate and intersecting the first active areas, in the cell region, wherein each of the cell gate structures comprises: a first barrier layer comprising a first region containing a first material and a second region containing a second material, wherein the first barrier layer is in the first trench and extends along a sidewall and a bottom surface of the first trench; a cell gate insulating layer containing the second material on a sidewall of the first barrier layer, and extending along the sidewall and the bottom surface of the first trench; a cell gate electrode layer on a sidewall of the cell gate insulating layer that fills the first trench; and a capping layer on a top surface of the cell gate electrode layer and a sidewall of the cell gate insulating layer, wherein a concentration of the second material in the first barrier layer is smaller than a concentration of the second material in the cell gate insulating layer.

According to a further aspect of the present disclosure, there is provided a method for fabricating a semiconductor device, comprising: forming an element isolation layer defining a plurality of active areas on a substrate; forming a first trench intersecting at least a portion of the plurality of active areas in the substrate; forming a barrier layer containing a first material along a sidewall and a bottom surface of the first trench; forming a gate insulating layer containing a second material different from the first material, on a sidewall of the barrier layer; and forming a gate electrode layer on a sidewall of the gate insulating layer and filling an inside of the first trench, wherein with respect to the sidewall of the first trench, a thickness of the barrier layer is less than or equal to half of a thickness of the gate insulating layer.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout diagram illustrating a semiconductor device according to some embodiments;

FIG. 2 shows a schematic layout of region R1 of FIG. 1;

FIG. 3 is a layout illustrating only word lines and active areas of FIG. 1;

FIG. 4 shows a schematic layout of region R2 of FIG. 1;

FIG. 5 is an exemplary cross-sectional view taken along line A-A of FIG. 2;

FIG. 6 is an exemplary cross-sectional view taken along line B-B of FIG. 2;

FIG. 7 is an exemplary cross-sectional view taken along line C-C of FIG. 2;

FIG. 8 is an exemplary cross-sectional view taken along line D-D of FIG. 2;

FIG. 9 is an enlarged view of part P of FIG. 8;

FIG. 10 is an exemplary cross-sectional view taken along line E-E of FIG. 4;

FIG. 11 is a schematic layout diagram illustrating a semiconductor device according to some embodiments;

FIGS. 12 and 13 are exemplary cross-sectional views taken along lines F-F and G-G of FIG. 11;

FIG. 14 is a schematic layout diagram illustrating a semiconductor device according to some embodiments;

FIGS. 15 and 16 are exemplary cross-sectional views taken along lines H-H and I-I of FIG. 15; and

FIGS. 17 to 23 are diagrams illustrating the intermediate steps of a method for fabricating a semiconductor device according to some embodiments.

### DETAILED DESCRIPTION OF THE EMBODIMENTS

Principles and embodiments of the present invention relate generally to addressing a silicon (Si) loss phenomenon in which the width of the active area is reduced due to the chemical change of the silicon (Si). In addition, a defect in which a gate trench may not be filled with a gate electrode due to oxide formation in the silicon of the active area may be reduced or avoided.

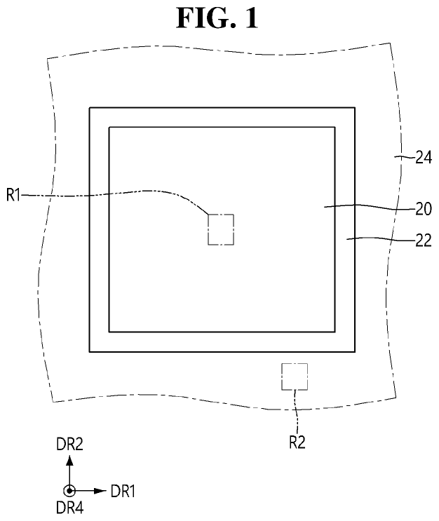

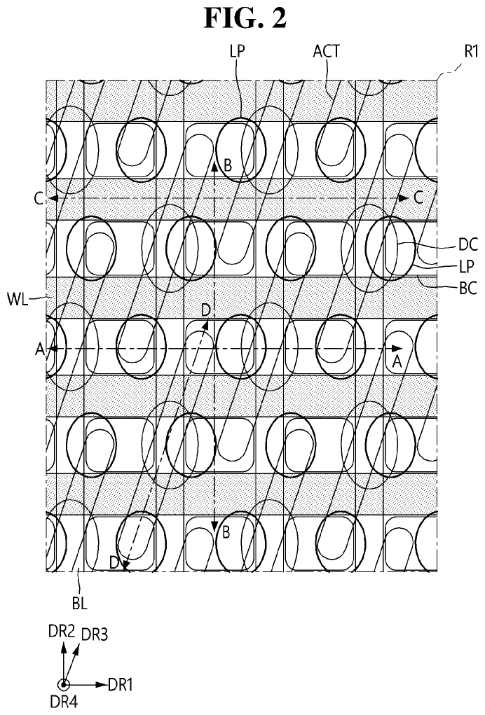

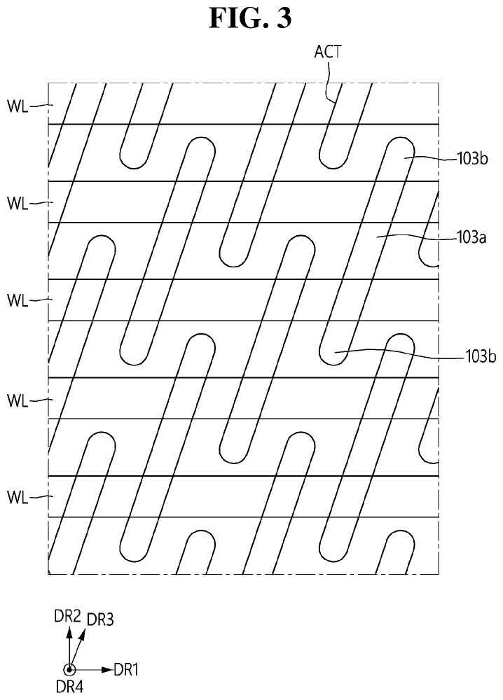

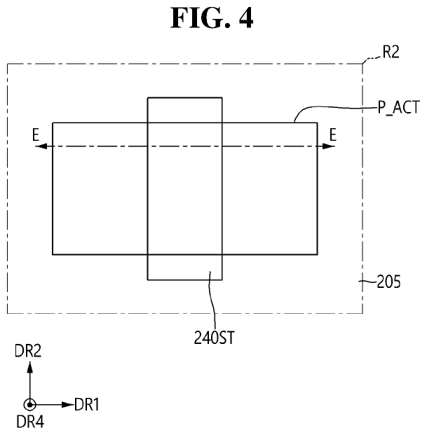

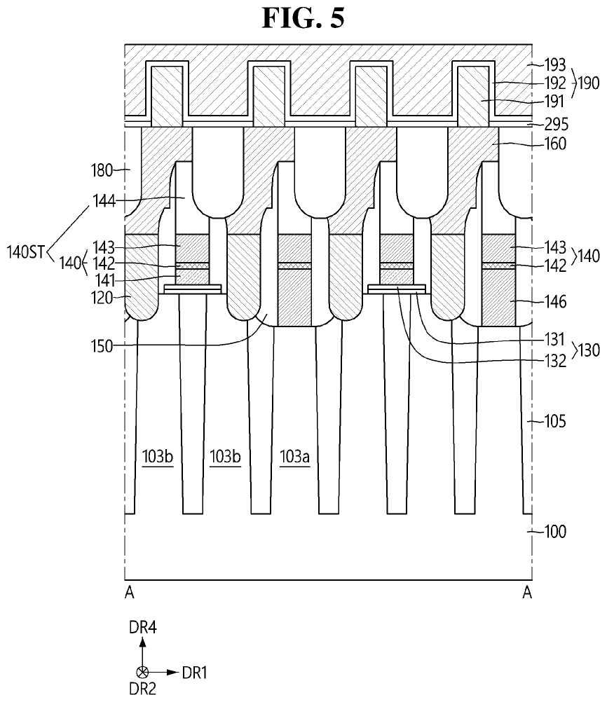

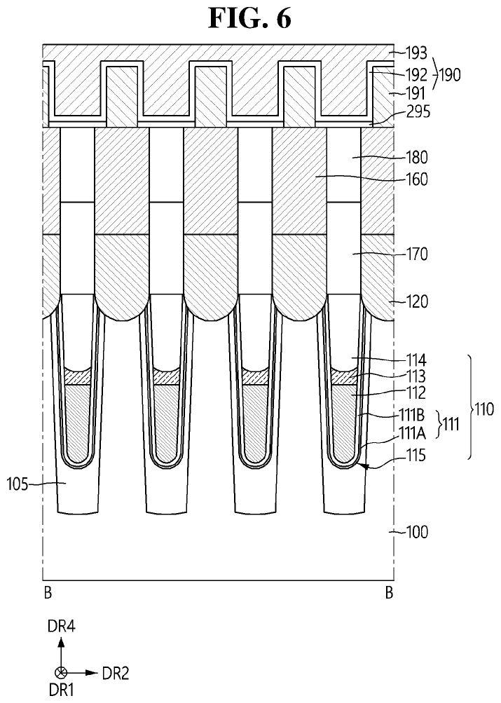

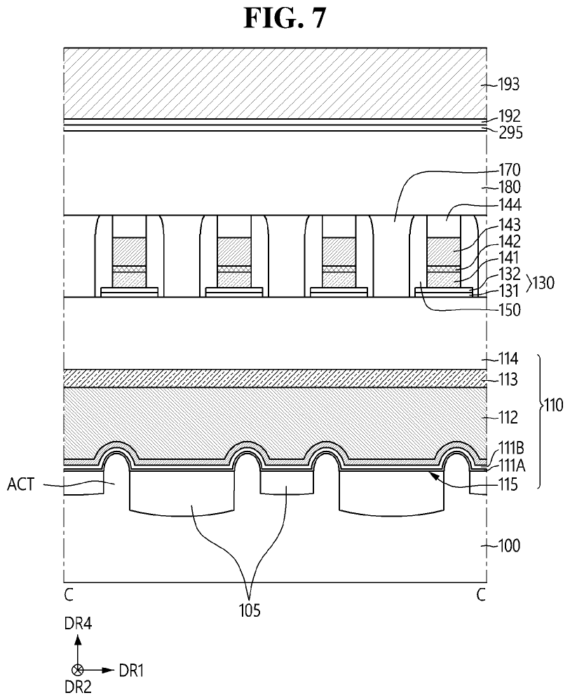

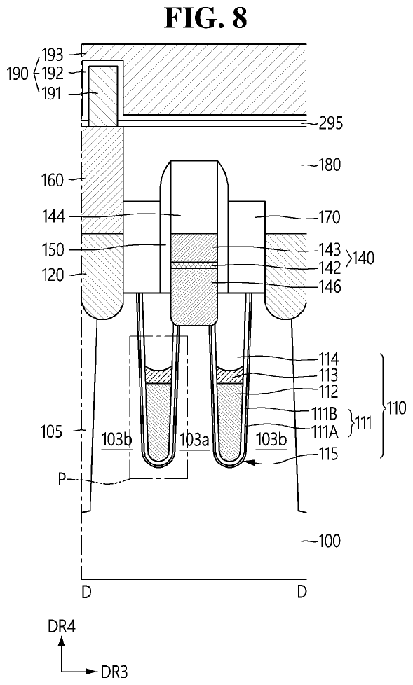

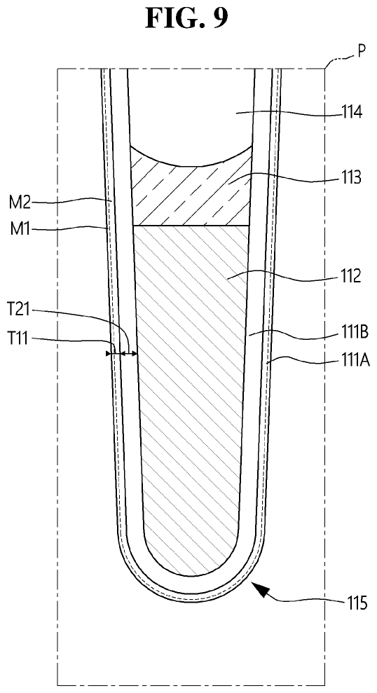

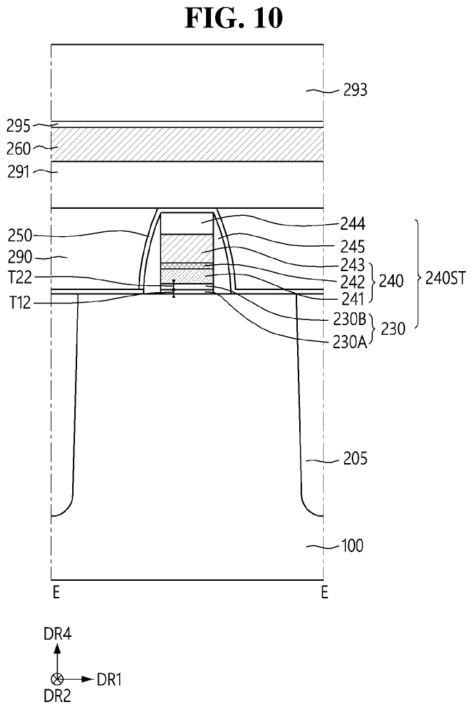

FIG. 1 is a schematic layout diagram illustrating a semiconductor device according to various embodiments. FIG. 2 shows a schematic layout of region R1 of FIG. 1. FIG. 3 is a layout illustrating word lines and active areas of FIG. 1. FIG. 4 shows a schematic layout of region R2 of FIG. 1. FIG. 5 is an exemplary cross-sectional view taken along line A-A of FIG. 2. FIG. 6 is an exemplary cross-sectional view taken along line B-B of FIG. 2. FIG. 7 is a cross-sectional view taken along line C-C of FIG. 2. FIG. 8 is a cross-sectional view taken along line D-D of FIG. 2. FIG. 9 is an enlarged view of part P of FIG. 8. FIG. 10 is a cross-sectional view taken along line E-E of FIG. 4.

In the drawings of the semiconductor device according to some embodiments, a dynamic random access memory (DRAM) is illustrated as an example, but the present disclosure is not limited thereto.

Referring to FIGS. 1 to 4, the semiconductor device according to some embodiments may include a cell region 20, a cell region isolation layer 22, and a peripheral region 24.

In various embodiments, the cell region isolation layer 22 may be formed along the perimeter of the cell region 20, where the cell region isolation layer 22 may surround the cell region 20. The cell region isolation layer 22 may separate the cell region 20 from the peripheral region 24, where the peripheral region 24 may surround the cell region isolation layer 22 and the cell region 20.

In various embodiments, the cell region 20 may include a plurality of cell active areas ACT, where the cell active area ACT may be defined by a cell element isolation layer 105 formed in a substrate 100 (see e.g., FIG. 5). As the design rule of the semiconductor device decreases, as illustrated, the cell active area ACT may be disposed in a diagonal or oblique bar shape. The cell active area ACT may extend in a third direction DR3.

In various embodiments, a plurality of gate electrodes extending in the first direction DR1 may be disposed across the cell active area ACT. The plurality of gate electrodes may extend in parallel to each other. The plurality of gate electrodes may be, for example, a plurality of word lines WL. The word lines WL may be arranged at equal intervals, where the width of the word line WL and/or the interval between the word lines WL may be determined according to the design rule.

In various embodiments, the word line WL may extend to the cell region isolation layer 22, where a part of the word line WL may overlap the cell region isolation layer 22 in a fourth direction DR4.

Each cell active area ACT may be divided into three portions by the two word lines WL extending in the first direction DR1. The cell active area ACT may include a storage connection area 103b and a bit line connection area 103a. The bit line connection area 103a may be positioned at the center portion of the cell active area ACT, and the storage connection area 103b may be positioned at an end of the cell active area ACT.

In various embodiments, the bit line connection area 103a may be an area connected to the bit line BL, and the storage connection area 103b may be an area connected to an information storage unit 190 (see e.g., FIG. 5). The bit line connection area 103a may correspond to a common drain region, and the storage connection area 103b may correspond to a source region. Each of the word lines WL and the bit line connection area 103a and the storage connection area 103b adjacent thereto may constitute a transistor.

In FIG. 3, when the transistor including each of the word lines WL and the bit line connection portion 103a and the storage connection portion 103b adjacent thereto is an NMOS, the storage connection portion 103b and the bit line connection portion 103a may include at least one of doped n-type impurities, for example, phosphorus (P), arsenic (As), antimony (Sb), or bismuth (Bi). When the transistor including each of the word lines WL and the bit line connection portion 103a and the storage connection portion 103b adjacent thereto is a PMOS, the storage connection portion 103b and the bit line connection portion 103a may include a doped p-type impurity, for example, boron (B).

In various embodiments, a plurality of bit lines BL extending in a second direction DR2 perpendicular to the word lines WL may be disposed on the Word Lines WL. The plurality of bit lines BL may extend in parallel to each other. The bit lines BL may be arranged at equal intervals. The width of the bit line BL and/or the interval between the bit lines BL may be determined according to the design rule.

In various embodiments, the bit line BL may extend to the cell region isolation layer 22. A part of the bit line BL may overlap the cell region isolation layer 22 in the fourth direction DR4. The fourth direction DR4 may be orthogonal to the first direction DR1, the second direction DR2, and the third direction DR3. The fourth direction DR4 may be a thickness direction of the substrate 100.

The semiconductor device, according to various embodiments may include various contact arrangements formed on the cell active areas ACT. Various contact arrangements may include, for example, direct contacts (DC), buried contacts (BC), landing pads (LP), and the like.

In various embodiments, a direct contact DC can refer to a contact that electrically connects the cell active area ACT to the bit line BL. The buried contact BC may be a contact that connects the cell active area ACT to a lower electrode 191 (see e.g., FIG. 5) of a capacitor. Due to the disposition structure, a contact area between the buried contact BC and the cell active area ACT may be small. Accordingly, in order to increase the contact area with the cell active area ACT and to increase the contact area with the lower electrode 191 (see e.g., FIG. 5), a conductive landing pad LP may be introduced.

In various embodiments, the landing pad LP may be disposed between the buried contact BC and the lower electrode 191 (see e.g., FIG. 5) of the capacitor. By expanding the contact area through the introduction of the landing pad LP, the contact resistance between the cell active area ACT and the capacitor lower electrode 191 may be reduced.

In various embodiments, the direct contact DC may be electrically connected to the bit line connection area 103a. The buried contact BC may be electrically connected to the storage connection area 103b. As the buried contacts BC are located at both ends of the cell active area ACT, the landing pads LP may be located adjacent to both ends of the cell active area ACT to at least partially overlap the buried contacts BC. The buried contacts BC may be formed to overlap the cell element isolation layer 105 (see e.g., FIG. 5) and the cell active areas ACT between the adjacent word lines WL and between the adjacent bit lines BL.

In various embodiments, the word lines WL may be buried in the substrate 100. The word lines WL may be disposed across the cell active areas ACT between the direct contacts DC or the buried contacts BC. As illustrated, two word lines WL may traverse one cell active area ACT. As the cell active area ACT extends along the third direction DR3, the word line WL may have an angle of less than 90 degrees with respect to the cell active area ACT.

In various embodiments, the direct contacts DC and the buried contacts BC may be arranged symmetrically. Accordingly, the direct contacts DC and the buried contacts BC may be disposed in a straight line along the first direction DR1 and the second direction DR2. In contrast to the direct contacts DC and the buried contacts BC, the landing pads LP may be arranged in a zigzag shape in the second direction DR2 in which the bit line BL extends, where the position of the landing pads LP may be staggered in the first direction DR1. The landing pads LP may be disposed to overlap the same side surface of each bit line BL in the first direction DR1 in which the word line WL extends.

In various embodiments, each of the landing pads LP in a first line may overlap a left side surface of the corresponding bit line BL, and each of the landing pads LP in a second line may overlap a right side surface of the corresponding bit line BL.

Referring to FIGS. 1 to 10, a semiconductor device according to various embodiments may include a plurality of cell gate structures 110, a plurality of bit line structures 140ST, a plurality of bit line contacts 146, the information storage unit 190, and a peripheral gate structure 240ST.

In various embodiments, the substrate 100 may include the cell region 20, the cell region isolation layer 22, and the peripheral region 24. The substrate 100 may be a silicon substrate or silicon-on-insulator (SOI) substrate. Alternatively, the substrate 100 may include silicon germanium, silicon germanium on insulator (SGOI), indium antimonide, a lead tellurium compound, indium arsenide, indium phosphide, gallium arsenide, or gallium antimonide, but is not limited thereto.

In various embodiments, the plurality of cell gate structures 110, the plurality of bit line structures 140ST, the plurality of bit line contacts 146, and the information storage unit 190 may be disposed in the cell region 20. A peri-gate structure 240ST may be disposed in the peripheral region 24.

The peripheral region 24 may include a peripheral active area P_ACT extending in the first direction DR1. The peripheral active area P_ACT may be defined by a peripheral element isolation layer 205 formed in the substrate 100 (see e.g., FIG. 10).

In various embodiments, the peripheral gate structure 240ST may be disposed on the peripheral active area P_ACT defined by the peripheral element isolation layer 205. The peripheral gate structure 240ST may extend in the second direction DR2, where the peripheral gate structure 240ST may intersect the peripheral active area P_ACT.

In various embodiments, the cell element isolation layer 105 may be formed in the substrate 100 of the cell region 20. The cell element isolation layer 105 may have a shallow trench isolation (STI) structure configured to provide element isolation characteristics. The cell element isolation layer 105 may define the cell active area ACT in the cell region 20.

In various embodiments, the cell active area ACT defined by the cell element isolation layer 105 may have a stadium shape (also referred to as obround or a discorectangle) having a short axis and a long axis, as shown in FIGS. 2 and 3. The cell active area ACT may have an oblique orientation or shape, where the cell active area ACT may have an angle of less than 90 degrees with respect to the word line WL formed in the cell element isolation layer 105. Further, the cell active area ACT may have an oblique orientation or shape, where the cell active area ACT may have an angle of less than 90 degrees with respect to the bit line BL formed on the cell element isolation layer 105.

In various embodiments, the cell region isolation layer 22 may have an STI structure. The cell region 20 may be defined by the cell region isolation layer 22.

In various embodiments, the cell element isolation layer 105 and the cell region isolation layer 22 may include, for example, at least one of a silicon oxide layer, a silicon nitride layer, or a silicon oxynitride layer, but are not limited thereto.

In various embodiments, the cell element isolation layer 105 and the cell region isolation layer 22 may be formed of a single insulating layer, but are not limited thereto. Depending on the widths of the cell element isolation layer 105 and the cell region isolation layer 22, the cell element isolation layer 105 and the cell region isolation layer 22 may be formed of a single insulating layer or a plurality of insulating layers.

In FIG. 5, it is shown that the top surface of the cell element isolation layer 105 and at least a portion of the top surface of the substrate 100 lie on the same plane. However, this is for simplicity of description, and the present disclosure is not limited thereto.

The cell gate structure 110 may be formed in the substrate 100 and the cell element isolation layer 105, as shown e.g., in FIG. 6. The cell gate structures 110 may be formed on the cell element isolation layer 105 and the cell active areas ACT defined by the cell element isolation layer 105. The cell gate structures 110 may be a multilayer structure that is separated from the substrate by the cell element isolation layer 105. A storage contact 120 may be positioned between adjacent pairs of the cell gate structure 110. A fence pattern 170 may be on the cell gate structure 110.

Each of the plurality of cell gate structures 110 may include a cell gate trench 115, a cell gate insulating layer 111, a cell gate electrode layer 112, a cell gate capping conductive layer 113, and a cell gate capping layer 114. The cell gate insulating layer 111 may include a first barrier layer 111A in the cell gate trench 115 and a first insulating layer 111B on the first barrier layer 111A. The cell gate capping layer 114 may fill the cell gate trench 115 remaining after the cell gate electrode layer 112 and the cell gate capping conductive layer 113 are formed.

In various embodiments, the cell gate electrode layer 112 may correspond to the word line WL, where for example, the cell gate electrode layer 112 may be the word line WL, as shown e.g., in FIG. 2. In various embodiments, the cell gate structure 110 may not include the cell gate capping conductive layer 113.

As shown in FIG. 7, along line C-C of FIG. 2, the cell gate trench 115 may be relatively deep in the cell element isolation layer 105 and relatively shallow in the cell active areas ACT. The cell element isolation layer 105 may be discontinuous along the first direction DR1. A bottom surface of the cell gate electrode layer 112 forming a word line WL may be curved and correspond to the shape of the cell gate trench 115, as shown e.g., in FIG. 6. The depth of the cell gate trench 115 in the cell element isolation layer 105 may be greater than the depth of the cell gate trench 115 in the cell active area ACT.

In various embodiments, the cell gate insulating layer 111 may extend along the sidewall and bottom surface of the cell gate trench 115. The cell gate insulating layer 111 may extend along the profile of at least a part of the cell gate trench 115.

In various embodiments, the cell gate insulating layer 111 may include a first barrier layer 111A on the cell active area ACT and a first insulating layer 111B on the first barrier layer 111A. The first barrier layer 111A may extend along the direction of the cell gate trench 115, where the first barrier layer 111A can cover the sidewall and bottom surface of the cell gate trench 115. The insulating layer 1111B may be on the sidewall of the first barrier layer 111A and extend along the sidewall and bottom surface of the cell gate trench 115. The first barrier layer 111A may be referred to as a first region of the cell gate insulating layer 111, and the first insulating layer 111B may be referred to as a second region of the cell gate insulating layer 111.

In various embodiments, the first barrier layer 111A may include a first material layer M1 containing a first material and a second material layer M2 containing a second material, where the first insulating layer 111B may include the second material. For example, the first material may include at least one of silicon, carbon, nitrogen, or oxygen, and the second material may include oxygen.

In various embodiments, the first material layer M1 may include both the first material and the second material, but may include a greater thickness of the first material than the second material. The second material layer M2 may include a greater thickness of the second material than the first material.

In various embodiments, the concentration of the second material in the first barrier layer 111A may be less than the concentration of the second material in the first insulating layer 111B. The concentration of the first material in the first barrier layer 111A may be greater than the concentration of the first material in the first insulating layer 111B. For example, the first insulating layer 111B may substantially not include the first material.

In some embodiments, the concentration of the first material or the second material may refer to the concentration of the material per unit volume.

In various embodiments, the concentration of the first material in the cell gate insulating layer 111 may increase as it gets closer to the cell active area ACT and decrease as it gets closer to the cell gate electrode layer 112. The concentration of the first material in the cell gate insulating layer 111 may be smaller in an area adjacent to the cell gate electrode layer 112 than in an area adjacent to the cell active area ACT.

In addition, the concentration of the second material in the cell gate insulating layer 111 may decrease as it gets closer to the cell active area ACT and increase as it gets closer to the cell gate electrode layer 112. In this case, the concentration of the second material in the first barrier layer 111A may decrease as it is closer to the cell active area ACT and increase as it is closer to the cell gate electrode layer 112. The concentration of the second material in the cell gate insulating layer 111 may be greater in an area adjacent to the cell gate electrode layer 112 than in an area adjacent to the cell active area ACT.

Referring to FIG. 9, a thickness T11 of the first barrier layer 111A may be smaller than a thickness T21 of the first insulating layer 111B with respect to the sidewall or bottom surface of the cell gate trench 115. For example, the thickness T11 of the first barrier layer 111A may be less than or equal to half of the thickness T21 of the first insulating layer 111B.

In various embodiments, the first insulating layer 111B may include, for example, at least one of silicon oxide, silicon nitride, silicon oxynitride, or a high-k material having a higher dielectric constant than silicon oxide. The high-k material may include, for example, at least one dielectric material selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

In various embodiments, the cell gate electrode layer 112 may be formed on the cell gate insulating layer 111, where the cell gate electrode layer 112 may cover at least a portion of the first insulating layer 111B on the sidewalls of the cell gate trench 115. The cell gate electrode layer 112 may fill a part of the cell gate trench 115. The cell gate capping conductive layer 113 may be formed on the cell gate electrode layer 112 and extend along the top surface of the cell gate electrode layer 112.

In various embodiments, the cell gate electrode layer 112 may include at least one of metal, metal alloy, conductive metal nitride, conductive metal carbonitride, conductive metal carbide, metal silicide, a doped semiconductor material, conductive metal oxynitride, or conductive metal oxide. The cell gate electrode layer 112 may include at least one of, for example, TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, or a combination thereof, but is not limited thereto. The cell gate capping conductive layer 113 may include, for example, polysilicon or polysilicon-germanium, but is not limited thereto. In various embodiments, the cell gate structure 110 may not include the cell gate capping conductive layer 113.

In various embodiments, the cell gate capping layer 114 may be disposed on the cell gate electrode layer 112 and the cell gate capping conductive layer 113. The cell gate capping layer 114 may fill the upper portion of the cell gate trench 115 remaining after the cell gate electrode layer 112 and the cell gate capping conductive layer 113 are formed. The cell gate insulating layer 111 is illustrated as extending along the sidewall of the cell gate capping layer 114, but is not limited thereto.

In various embodiments, the cell gate capping layer 114 may be disposed on the top surface of the cell gate electrode layer 112 and the sidewall of the first insulating layer 111B. The bottom surface of the cell gate capping layer 114 may be in contact with the top surface of the cell gate electrode layer 112, but may not be in contact with each of the top surface of the first barrier layer 111A and the top surface of the first insulating layer 111B.

In various embodiments, the cell gate capping layer 114 may include, for example, at least one of silicon nitride (SiN), silicon oxynitride (SiON), silicon oxide (SiO2), silicon carbonitride (SiCN), silicon oxycarbonitride (SiOCN), or a combination thereof.

In FIG. 6, the top surface of the cell element isolation layer 105 may extend toward the top surface of the cell gate capping layer 114, but is not limited thereto.

As shown in FIG. 8, an impurity doped region may be formed on at least one side of the cell gate structure 110. The impurity doped region may be a source/drain region of a transistor. An impurity doped region may be formed in each of the storage connection portion 103b and the bit line connection portion 103a of FIG. 3.

In various embodiments, the bit line structure 140ST may include a cell conductive line 140, a cell line capping layer 144, and a bit line spacer 150, as shown e.g., in FIG. 5.

In various embodiments, the cell conductive line 140 may be disposed on the substrate 100 on which the cell gate structure 110 is formed and on the cell element isolation layer 105. The cell conductive line 140 may intersect the cell element isolation layer 105 and the cell active area ACT defined by the cell element isolation layer 105. The cell conductive line 140 may be formed to intersect the cell gate structure 110. Here, the cell conductive line 140 may correspond to the bit line BL. For example, the cell conductive line 140 may be the bit line BL of FIG. 2.

In various embodiments, the cell conductive line 140 may include, for example, at least one of a semiconductor material doped with impurities, a conductive silicide compound, a conductive metal nitride, a two-dimensional (2D) material, a metal, or a metal alloy. In the semiconductor device according to various embodiments, the 2D material may be a metallic material and/or a semiconductor material. The 2D material may include a 2D allotrope or a 2D compound. For example, the two-dimensional (2D) material may include at least one of graphene, molybdenum disulfide (MoS2), molybdenum diselenide (MoSe2), tungsten diselenide (WSe2), or tungsten disulfide (WS2), but is not limited thereto.

In various embodiments, the cell conductive line 140 may be a multilayer. The cell conductive line 140 may include, for example, a first cell conductive layer 141, a second cell conductive layer 142, and a third cell conductive layer 143. The first to third cell conductive layers 141, 142, and 143 may be sequentially stacked on the substrate 100 and the cell element isolation layer 105. Although the cell conductive line 140 is illustrated as being a triple layer, the present disclosure is not limited thereto, and may have a greater or fewer number of layers.

Each of the first to third cell conductive layers 141, 142, and 143 may include, for example, at least one of a semiconductor material doped with impurities, a conductive silicide compound, a conductive metal nitride, a metal, or a metal alloy. For example, the first cell conductive layer 141 may include a doped semiconductor material, the second cell conductive layer 142 may include at least one of a conductive silicide compound or a conductive metal nitride, the third cell conductive layer 143 may include at least one of a metal or a metal alloy, but the present disclosure is not limited thereto.

In various embodiments, the bit line contact 146 may be formed between the cell conductive line 140 and the substrate 100, where the cell conductive line 140 may be formed on the bit line contact 146. For example, the bit line contact 146 may be formed at a point where the cell conductive line 140 intersects a central portion of the cell active area ACT having the stadium shape. The bit line contact 146 may be formed between the bit line connection area 103a and the cell conductive line 140.

In various embodiments, the bit line contact 146 may electrically connect the cell conductive line 140 to the substrate 100. Here, the bit line contact 146 may correspond to the direct contact (DC). The bit line contact 146 may include, for example, at least one of a semiconductor material doped with impurities, a conductive silicide compound, conductive metal nitride, or metal.

In FIG. 5, the cell conductive line 140 may include the second cell conductive layer 142 and the third cell conductive layer 143 in an area overlapping the top surface of the bit line contact 146, where the second cell conductive layer 142 is in electrical contact with the bit line contact 146. The cell conductive line 140 may include the first to third cell conductive layers 141, 142, and 143 in an area that does not overlap the top surface of the bit line contact 146.

In various embodiments, the cell line capping layer 144 may be disposed on the cell conductive line 140. The cell line capping layer 144 may extend in the second direction DR2 along the top surface of the cell conductive line 140. The cell line capping layer 144 may include, for example, at least one of a silicon nitride layer, silicon oxynitride, silicon carbonitride, or silicon oxycarbonitride.

In the semiconductor device according to various embodiments, the cell line capping layer 144 may include a silicon nitride layer. Although it is illustrated that the cell line capping layer 144 is a single layer, the present disclosure is not limited thereto. Unlike the illustration, the cell line capping layer 144 may be formed of a multilayer.

In various embodiments, the bit line spacer 150 may be disposed on the sidewalls of the cell conductive line 140 and the cell line capping layer 144. The bit line spacer 150 may be elongated in the second direction DR2.

Although the bit line spacer 150 is illustrated as being a single layer, this is merely for simplicity of description and the present disclosure is not limited thereto. The bit line spacer 150 may have a multilayer structure. The bit line spacer 150 may include, for example, one of a silicon oxide layer, a silicon nitride layer, a silicon oxynitride layer (SiON), a silicon oxycarbonitride layer (SiOCN), air, or combinations thereof, but is not limited thereto.

In various embodiments, a cell insulating layer 130 may be formed on the substrate 100 and the cell element isolation layer 105. More specifically, the cell insulating layer 130 may be formed on the top surfaces of the cell element isolation layer 105 and the substrate 100 on which the bit line contact 146 is not formed. The cell insulating film 130 may be formed between the substrate 100 and the cell conductive line 140, and between the cell element isolation layer 105 and the cell conductive line 140.

In various embodiments, the cell insulating layer 130 may be a single layer, but as shown, the cell insulating layer 130 may be a multilayer including a first cell insulating layer 131 and a second cell insulating layer 132. For example, the first cell insulating layer 131 may include a silicon oxide layer, and the second cell insulating layer 132 may include a silicon nitride layer, but they are not limited thereto. The cell insulating layer 130 may be a triple layer including a silicon oxide layer, a silicon nitride layer, and a silicon oxide layer, but is not limited thereto.

In a portion of the cell conductive line 140, where the bit line contact 146 is formed, the bit line spacer 150 may be formed on the substrate 100 and at least a portion of the cell element isolation layer 105. The bit line spacer 150 may be disposed on the sidewalls of the cell conductive line 140, the cell line capping layer 144, and the bit line contact 146.

In various embodiments, the bit line spacer 150 may be disposed on the cell insulating layer 130 in the remaining portion of the cell conductive line 140, where the bit line contact 146 is not formed. The bit line spacer 150 may be disposed on the sidewalls of the cell conductive line 140 and the cell line capping layer 144.

A fence pattern 170 may be disposed on the substrate 100 and the cell element isolation layer 105, as shown in FIG. 6. The fence pattern 170 may be formed to overlap the cell gate structure 110 formed in the substrate 100 and the cell element isolation layer 105.

In various embodiments, the fence pattern 170 may be disposed between the bit line structures 140ST extending in the second direction DR2, as shown in e.g., FIG. 7. The fence pattern 170 may include, for example, at least one of silicon oxide, silicon nitride, silicon oxynitride, or a combination thereof.

In various embodiments, a storage contact 120 may be disposed between the cell conductive lines 140 adjacent in the first direction DR1, as shown e.g., in FIG. 5. A storage contact 120 may be disposed between the cell conductive lines 140 adjacent in the first direction DR1. More specifically, the storage contact 120 may be disposed between the bit line structures 140ST. The storage contact 120 may be disposed between the adjacent fence patterns 170 in the second direction DR2, as shown e.g., in FIG. 6.

In various embodiments, the storage contact 120 may overlap the substrate 100 and the cell element isolation layer 105 between the adjacent cell conductive lines 140. The storage contact 120 may be electrically connected to the cell active area ACT. More specifically, the storage contact 120 may be electrically connected to the storage connection portion 103b. Here, the storage contact 120 may correspond to the buried contact BC of FIG. 2.

In various embodiments, the storage contact 120 may include, for example, at least one of a semiconductor material doped with impurities, a conductive silicide compound, conductive metal nitride, or a metal.

In various embodiments, a storage pad 160 may be formed on the storage contact 120. The storage pad 160 may be electrically connected to the storage contact 120. The storage pad 160 may be electrically connected to the storage connection portion 103b of the cell active area ACT. Here, the storage pad 160 may correspond to the landing pad LP.

In various embodiments, the storage pad 160 may overlap a portion of the top surface of the bit line structure 140ST. The storage pad 160 may include, for example, at least one of a conductive metal nitride, a conductive metal carbide, a metal, or a metal alloy.

In various embodiments, a pad separation insulating layer 180 may be formed adjacent to the storage pad 160 and the bit line structure 140ST, where a fence pattern 170 can electrically separate the storage pad 160 and storage contact 120 from the cell conductive line 140, the cell line capping layer 144, and the bit line spacer 150 of the bit line structure 140ST, as shown in e.g., FIG. 8. The pad separation insulating layer 180 may be disposed on the fence pattern 170, cell line capping layer 144 and the bit line spacers 150. The pad separation insulating layer 180 may define the storage pads 160 forming a plurality of isolation regions. The pad separation insulating layer 180 may not cover the top surface of the storage pad 160. The height of the top surface of the storage pad 160 may be the same as the height of the top surface of the pad separation insulating layer 180 in reference to the top surface of the substrate 100.

In various embodiments, the pad separation insulating layer 180 may include an electrical insulating material to electrically separate the plurality of storage pads 160 from each other. The pad separation insulating layer 180 may include, for example, at least one of a silicon oxide layer, a silicon nitride layer, a silicon oxynitride layer, a silicon oxycarbonitride layer, or a silicon carbonitride layer.

An etch stop layer 295 may be disposed on the top surface of the storage pad 160 and the top surface of the pad separation insulating layer 180. The etch stop layer 295 may include, for example, at least one of silicon nitride (SiN), silicon carbonitride (SiCN), silicon oxycarbonitride (SiOCN), silicon oxycarbide (SiOC), or silicon boron nitride (SiBN).

In various embodiments, an information storage unit 190 may be formed on the storage pad 160. The information storage unit 190 may be electrically connected to the storage pad 160. A portion of the information storage unit 190 may be disposed within the etch stop layer 295.

In various embodiments, the information storage unit 190 may include, for example, a capacitor, but is not limited thereto. In various embodiments, the information storage unit 190 includes the lower electrode 191, a capacitor dielectric layer 192, and an upper electrode 193. For example, the upper electrode 193 may be a plate upper electrode having a plate shape.

In various embodiments, the lower electrode 191 may be disposed on the storage pad 160, where the lower electrode 191 may be in electrical contact with the storage pad 160. The lower electrode 191 may have, for example, a pillar shape.

In various embodiments, the capacitor dielectric layer 192 is formed on the lower electrode 191. The capacitor dielectric layer 192 may be formed along the profile of the lower electrode 191, where the capacitor dielectric layer 192 may be on the top surface and at least a portion of the sidewalls of the lower electrode 191. The upper electrode 193 may be formed on the capacitor dielectric layer 192, where the upper electrode 193 may surround the outer wall of the lower electrode 191. Although the upper electrode 193 is illustrated as being a single layer, this is only for simplicity of description, and the present disclosure is not limited thereto.

Each of the lower electrode 191 and the upper electrode 193 may include, for example, a doped semiconductor material, conductive metal nitride (e.g., titanium nitride, tantalum nitride, niobium nitride, tungsten nitride, or the like), metal (e.g., ruthenium, iridium, titanium, tantalum, or the like), conductive metal oxide (e.g., iridium oxide, niobium oxide, or the like), or the like, but the present disclosure is not limited thereto.

In various embodiments, the capacitor dielectric layer 192 may include, for example, one of silicon oxide, silicon nitride, silicon oxynitride, a high-k material, or a combination thereof, but is not limited thereto. In the semiconductor device according to some embodiments, the capacitor dielectric layer 192 may include a stacked structure in which zirconium oxide, aluminum oxide and zirconium oxide are sequentially stacked. In the semiconductor device according to some embodiments, the capacitor dielectric layer 192 may include a dielectric layer including hafnium (Hf). In the semiconductor device according to some embodiments, the capacitor dielectric layer 192 may have a stacked structure including a ferroelectric material layer and a paraelectric material layer.

In various embodiments, the peripheral element isolation layer 205 may be formed in the substrate 100 in the peripheral region 24, as shown e.g., in FIG. 10. The peripheral element isolation layer 205 may define the peripheral active area P_ACT in the peripheral region 24. The top surface of the peripheral element isolation layer 205 is illustrated as being on the same plane as the top surface of the substrate 100, but is not limited thereto. The peripheral element isolation layer 205 may include, for example, at least one of a silicon oxide layer, a silicon nitride layer, or a silicon oxynitride layer, but the present disclosure is not limited thereto.

In various embodiments, the peripheral gate structure 240ST may be disposed on the substrate 100 in the peripheral region 24.

In various embodiments, the peripheral gate structure 240ST may include a peripheral gate insulating layer 230, a peripheral gate conductive layer 240, and a peripheral capping layer 244 sequentially stacked on the substrate 100, as shown e.g., in FIG. 10. The peripheral gate structure 240ST may include a peripheral spacer 245 disposed on the sidewall of the peripheral gate insulating layer 230, the sidewall of the peripheral gate conductive layer 240, and the sidewall of the peripheral capping layer 244.

In various embodiments, the peripheral gate insulating layer 230 may include a second barrier layer 230A on the peripheral active area P_ACT and a second insulating layer 230B on the second barrier layer 230A.

In various embodiments, the second barrier layer 230A may include a first material and a second material. The second insulating layer 230B may include the second material. In some embodiments, the first material may include at least one of silicon, carbon, nitrogen, or oxygen, and the second material may include oxygen.

In various embodiments, the concentration of the second material in the second barrier layer 230A may be less than the concentration of the second material in the second insulating layer 230B. The concentration of the first material in the second barrier layer 230A may be greater than the concentration of the first material in the second insulating layer 230B. For example, the second insulating layer 230B may not include the first material.

In various embodiments, the concentration of the first material in the peripheral gate insulating layer 230 may increase as it gets closer to the peripheral active area P_ACT and decrease as it gets closer to the peripheral gate conductive layer 240. In addition, the concentration of the second material in the peripheral gate insulating layer 230 may decrease as it gets closer to the peripheral active area P_ACT and increase as it gets closer to the peripheral gate conductive layer 240. The concentration of the second material in the second barrier layer 230A may decrease as it gets closer to the peripheral active area P_ACT and increase as it gets closer to the peripheral gate conductive layer 240.

Referring to FIG. 10, with respect to the fourth direction DR4, a thickness T12 of the second barrier layer 230A may be smaller than a thickness T22 of the second insulating layer 230B. For example, the thickness T12 of the second barrier layer 230A may be less than or equal to half of the thickness T22 of the second insulating layer 230B.

In various embodiments, the second insulating layer 230B may include, for example, at least one of silicon oxide, silicon nitride, silicon oxynitride, or a high-k material having a higher dielectric constant than silicon oxide. The high-k material may include, for example, at least one dielectric material selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

In various embodiments, the peripheral gate conductive layer 240 may include first to third peripheral conductive layers 241, 242, and 243 sequentially stacked on the peripheral gate insulating layer 230. For example, an additional conductive layer may not be disposed between the peripheral gate conductive layer 240 and the peripheral gate insulating layer 230. An additional conductive layer such as a work function conductive layer may be disposed between the peripheral gate conductive layer 240 and the peripheral gate insulating layer 230.

Although it is illustrated that one peripheral gate structure 240ST is disposed between the adjacent peripheral element isolation layers 205, this is only for simplicity of description, and is not limited thereto.

In various embodiments, a peripheral etch stop layer 250 may be disposed on the substrate 100 and the sidewalls of the peripheral spacer 245. The peripheral etch stop layer 250 may be formed along the profile of the peripheral gate structure 240ST and the top surface of the substrate 100. The peripheral etch stop layer 250 may be between the peripheral capping layer 244 and an overlying insertion interlayer insulating layer 291.

In various embodiments, the peripheral etch stop layer 250 may include, for example, at least one of a silicon nitride layer, silicon oxynitride, silicon carbonitride, or silicon oxycarbonitride.

In various embodiments, a first peripheral interlayer insulating layer 290 may be disposed on the peripheral etch stop layer 250. The first peripheral interlayer insulating layer 290 may be disposed around the peripheral gate structure 240ST, where the peripheral etch stop layer 250 can separate the first peripheral interlayer insulating layer 290 from the peripheral gate structure 240ST.

In various embodiments, an insertion interlayer insulating layer 291 may be disposed on the peripheral gate structure 240ST and the first peripheral interlayer insulating layer 290. The insertion interlayer insulating layer 291 may cover the peripheral gate structure 240ST and the first peripheral interlayer insulating layer 290. The peripheral etch stop layer 250 may separate the peripheral capping layer 244 from the insertion interlayer insulating layer 291.

In various embodiments, the insertion interlayer insulating layer 291 may include a material different from that of the first peripheral interlayer insulating layer 290. The insertion interlayer insulating layer 291 may include, for example, a nitride-based insulating material, where for example, the insertion interlayer insulating layer 291 may include silicon nitride.

Accordingly, in an etching process included in the process of fabricating the information storage unit 190, the insertion interlayer insulating layer 291 may protect the first peripheral interlayer insulating layer 290. In the etching process included in the process of fabricating the information storage unit 190, the insertion interlayer insulating layer 291 may prevent defects caused by etching the first peripheral interlayer insulating layer 290.

In various embodiments, a peripheral wiring line 260 may be disposed on the insertion interlayer insulating layer 291. The peripheral contact plugs connected to the peripheral wiring lines 260 may be disposed on both sides of the peripheral gate structure 240ST. The peripheral contact plug may penetrate the insertion interlayer insulating layer 291 and the first peripheral interlayer insulating layer 290 and extend to the substrate 100 of the peripheral region 24.

In various embodiments, the peripheral wiring line 260 and the peripheral contact plug may include the same conductive material as the storage pad 160.

In various embodiments, the etch stop layer 295 may be disposed on the peripheral wiring line 260. A second peripheral interlayer insulating layer 293 may be disposed on the etch stop layer 295. The second peripheral interlayer insulating layer 293 may cover the sidewall of the first upper electrode 193. The second peripheral interlayer insulating layer 293 may include an insulating material.

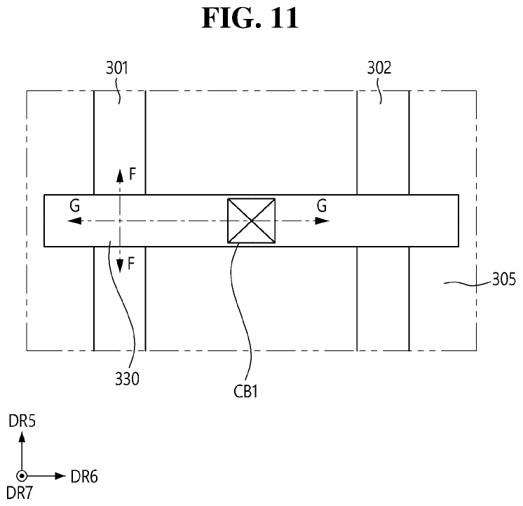

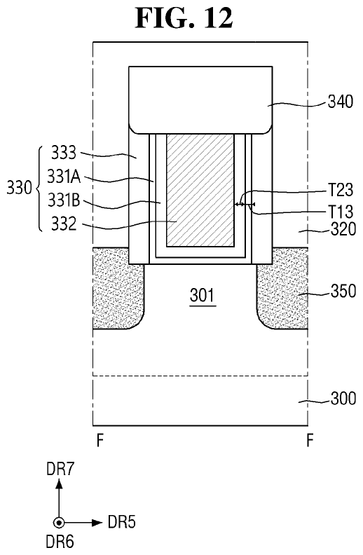

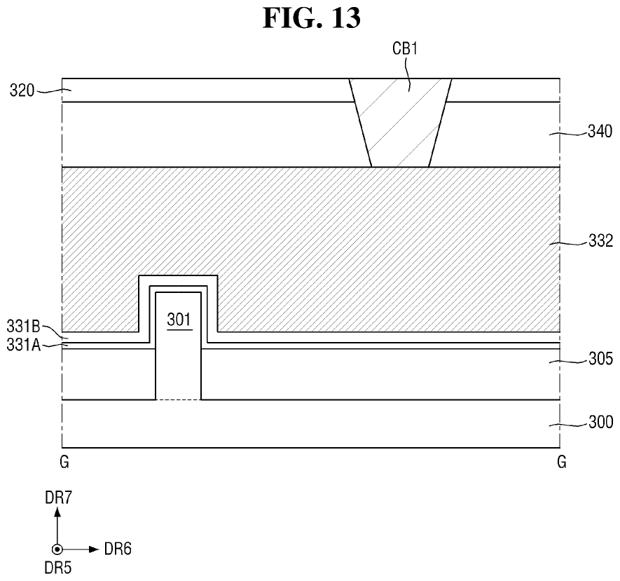

FIG. 11 is a schematic layout diagram illustrating a semiconductor device according to some embodiments. FIGS. 12 and 13 are exemplary cross-sectional views taken along lines F-F and G-G of FIG. 11. For simplicity of description, the following description will focus on differences from the description with reference to FIGS. 1 to 10.

For reference, FIG. 11 schematically illustrates a first fin-shaped pattern 301, a second fin-shaped pattern 302, and a gate structure 330, where a first gate contact CB1 is disposed between the first fin-shaped pattern 301 and the second fin-shaped pattern 302.

Referring to FIGS. 11 to 13, a semiconductor device according to various embodiments may include a substrate 300, the first fin-shaped pattern 301, the second fin-shaped pattern 302, a field insulating layer 305, the gate structure 330, an interlayer insulating layer 320, a capping pattern 340, a source/drain region 350, and the first gate contact CB1. In some embodiments, the first and second fin-shaped patterns 301 and 302 may mean active areas.

In various embodiments, the substrate 300 may be a bulk silicon or silicon-on-insulator (SOI) substrate. Alternatively, the substrate 300 may be a silicon substrate or may include other materials such as silicon germanium, silicon germanium on insulator (SGOI), indium antimonide, a lead tellurium compound, indium arsenide, indium phosphide, gallium arsenide, or gallium antimonide. However, the technical spirit of the present disclosure is not limited thereto. Hereinafter, for simplicity of description, it is assumed that the substrate 300 is a substrate containing silicon.

In various embodiments, the first fin-shaped pattern 301 and the second fin-shaped pattern 302 may be defined by the field insulating layer 305. The first fin-shaped pattern 301 and the second fin-shaped pattern 302 may be spatially spaced apart, but may be adjacent to each other. The first fin-shaped pattern 301 may extend in a fifth direction DR5 of the substrate 100. The second fin-shaped pattern 302 may be spaced apart from the first fin-shaped pattern 301 in a sixth direction DR6 of the substrate 100 and extend in the fifth direction DR5.

In various embodiments, the field insulating layer 305 may be formed to surround the first fin-shaped pattern 301 and the second fin-shaped pattern 302. The field insulating layer 305 may be disposed between the first fin-shaped pattern 301 and the second fin-shaped pattern 302, and may be directly in contact with the first fin-shaped pattern 301 and the second fin-shaped pattern 302. The field insulating layer 305 may include, for example, at least one of a silicon oxide layer, a silicon nitride layer, a silicon oxynitride layer, or a combination thereof.

In various embodiments, the gate structure 330, as shown e.g., in FIG. 12, may extend in the sixth direction DR6 intersecting the fifth direction DR5 on the first fin-shaped pattern 301. The gate structure 330 may include a gate spacer 333, a barrier layer 331A, an insulating layer 331B, and a gate electrode layer 332. The gate electrode layer can be formed on a sidewall of the gate insulating layer and fill an inside of a first trench. The barrier layer 331A and the insulating layer 331B may be referred to as a gate insulating layer.

Although the gate spacer 333 is illustrated as being formed of a single layer, the technical spirit of the present disclosure is not limited thereto. In some embodiments, the gate spacer 333 may be formed of a plurality of layers. The gate spacer 333 may include, for example, at least one of silicon nitride (SiN), silicon oxynitride (SiON), silicon oxide (SiO2), silicon oxycarbonitride (SiOCN) or a combination thereof. In some embodiments, the gate spacers 333 may serve as a guide for forming a self-aligned contact. Accordingly, the gate spacer 333 may include a material having an etch selectivity with respect to the interlayer insulating layer 320 to be described later.

In various embodiments, the barrier layer 331A may include a first material and a second material. The insulating layer 331B may include a second material. In some embodiments, the first material may include at least one of silicon, carbon, nitrogen, or oxygen, and the second material may include oxygen.

In various embodiments, the concentration of the second material in the barrier layer 331A may be less than the concentration of the second material in the insulating layer 331B. The concentration of the first material in the barrier layer 331A may be greater than the concentration of the first material in the insulating layer 331B. For example, the insulating layer 331B may not include the first material.

In various embodiments, the concentration of the first material in the gate insulating layer may increase as it gets closer to the first fin-shaped pattern 301 and decrease as it gets closer to the gate electrode layer 332. In addition, the concentration of the second material in the gate insulating layer may decrease as it gets closer to the first fin-shaped pattern 301 and increase as it gets closer to the gate electrode layer 332. The concentration of the second material in the barrier layer 331A may decrease as it gets closer to the first fin-shaped pattern 301 and increase as it gets closer to the gate electrode layer 332.

Referring to FIG. 12, a thickness T13 of the barrier layer 331A may be smaller than a thickness T23 of the insulating layer 331B with respect to the fifth direction DR5 or a seventh direction DR7.

In various embodiments, the insulating layer 331B may include, for example, at least one of silicon oxide, silicon nitride, silicon oxynitride, or a high-k material having a higher dielectric constant than silicon oxide. The high-k material may include, for example, at least one dielectric material selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

In various embodiments, the gate electrode layer 332 may include a metal nitride including at least one of titanium (Ti) or tantalum (Ta), and/or at least one of W, Al, Co, Cu, Ru, Ni, Pt, or Ni—Pt. It is illustrated in the drawings that the gate electrode layer 332 is formed as a single layer, but the technical spirit of the present disclosure is not limited thereto. In various embodiments, the gate electrode layer 332 may include a plurality of layers.

In various embodiments, the interlayer insulating layer 320 may be formed on the substrate 300, where the interlayer insulating layer 320 may surround the capping pattern 340, and the outer wall of the spacer 333. The interlayer insulating layer 320 may include, for example, silicon oxide (SiO2), silicon nitride (SiN), silicon oxynitride (SiON), flowable oxide (FOX), tonen silazene (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), Xerogel, Aerogel, amorphous fluorinated carbon, organo silicate glass (OSG), parylene, bis-benzocyclobutene (BCB), SILK, polyimide, a porous polymeric material, or a combination thereof, but the technical spirit of the present disclosure is not limited thereto.

In various embodiments, the capping pattern 340 may be formed on the gate structure 330 and cover the gate structure 330. The top surface of the capping pattern 340 may be coplanar with the top surface of the interlayer insulating layer 320. The capping pattern 340 may be in contact with a sidewall of the interlayer insulating layer 320.

Because the capping pattern 340 may serve as a guide to form a self-aligned contact, the capping pattern 340 may include a material that can be etched selectivity with respect to the interlayer insulating layer 320. The capping pattern 340 may include an insulating material, and may include, for example, at least one of silicon nitride (SiN), silicon oxynitride (SiON), silicon oxide (SiO2), silicon carbonitride (SiCN), silicon oxycarbonitride (SiOCN), or a combination thereof.

In various embodiments, the first gate contact CB1, as shown e.g., in FIG. 13, may be disposed on the gate structure 330 and may be disposed between the first fin-shaped pattern 301 and the second fin-shaped pattern 302.

In various embodiments, the first gate contact CB1 may penetrate the capping pattern 340 and may be in electrical contact with the gate structure 330, where the the first gate contact CB1 can be in electrical contact with the gate electrode layer 332. A material of the first gate contact CB1 may be tungsten (W), but is not limited thereto.

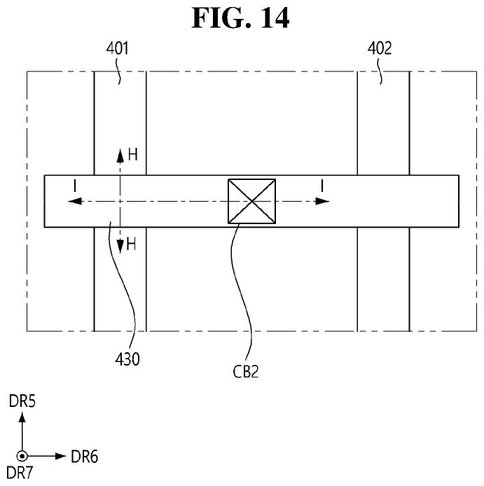

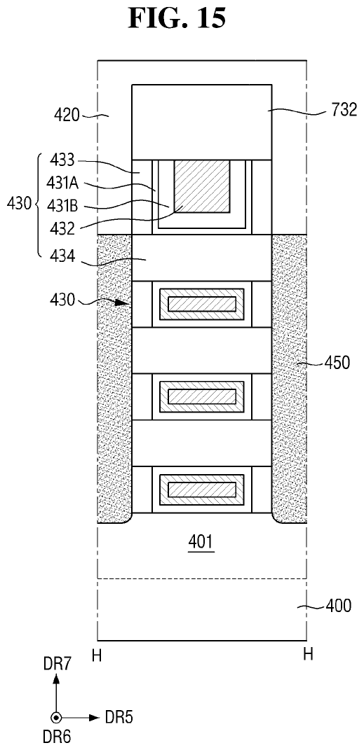

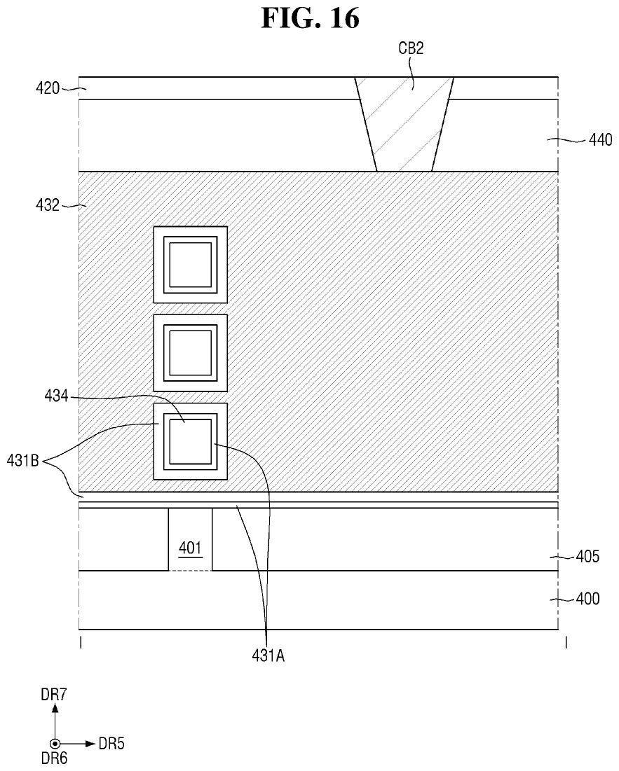

FIG. 14 is a schematic layout diagram illustrating a semiconductor device according to various embodiments. FIGS. 15 and 16 are exemplary cross-sectional views taken along lines H-H and I-I of FIG. 15. For simplicity of description, the following description will focus on differences from the description with reference to FIGS. 1 to 13.

Referring to FIGS. 14 to 16, a semiconductor device according to various embodiments may include a substrate 400, a first fin-shaped pattern 401, a second fin-shaped pattern 402, a field insulating layer 405, a gate structure 430, an interlayer insulating layer 420, a capping pattern 440, a source/drain region 450, a second gate contact CB2, and a plurality of nanosheets 434.

In various embodiments, the configuration of the embodiment may correspond to each of the substrate 300, the first fin-shaped pattern 301, the second fin-shaped pattern 302, the field insulating layer 305, the gate structure 330, the interlayer insulating layer 320, the capping pattern 340, the source/drain region 350, and the first gate contact CB1 in FIGS. 11 to 13, except for the plurality of nanosheets 434.

In various embodiments, three nanosheets 434 may be sequentially formed on the substrate 400, but the technical spirit of the present disclosure is not limited thereto. In various embodiments, the number of nanosheets formed on the substrate 400 may be different. The three nanosheets 434 may be sequentially stacked and spaced apart from each other in the seventh direction DR7 on the substrate 400.

Each of the plurality of nanosheets 434 may extend in the fifth direction DR5. In addition, the top surface of the uppermost nanosheet on the first fin-shaped pattern 401 may be formed on substantially the same plane as the top surface of the source/drain region 450. However, the technical spirit of the present disclosure is not limited thereto.

In various embodiments, the plurality of nanosheets 434 may be surrounded by the gate structure 430. The plurality of nanosheets 434 may be surrounded by a gate insulating layer, where the barrier layer 431A and the insulating layer 431B may be referred to as a gate insulating layer. The plurality of nanosheets 434 may each be surrounded by a gate electrode layer 432, where the gate electrode layers 432 surround the gate insulating layer.

Each of the plurality of nanosheets 434 may be used as a channel region, and materials may vary depending on the shape of a semiconductor device according to some embodiments.

When a semiconductor device according to some embodiments is an NMOS transistor, each of the plurality of nanosheets 434 may include, for example, a material with high electron mobility, and when a semiconductor device according to some embodiments is a PMOS transistor, each of the plurality of nanosheets 434 may include, for example, a material with high hole mobility.

In various embodiments, the barrier layer 431A may include a first material and a second material. The insulating layer 431B may include the second material. In some embodiments, the first material may include at least one of silicon, carbon, nitrogen, or oxygen, and the second material may include oxygen.

In various embodiments, the concentration of the second material in the barrier layer 431A may be less than the concentration of the second material in the insulating layer 431B. The concentration of the first material in the barrier layer 431A may be greater than the concentration of the first material in the insulating layer 431B. In various embodiments, the insulating layer 431B may not include the first material.

In various embodiments, the concentration of the first material in the gate insulating layer may increase as it gets closer to the first fin-shaped pattern 401 and decrease as it gets closer to the gate electrode layer 432. In addition, the concentration of the second material in the gate insulating layer may decrease as it gets closer to the first fin-shaped pattern 401 and increase as it gets closer to the gate electrode layer 432. The concentration of the second material in the barrier layer 431A may decrease as it gets closer to the first fin-shaped pattern 401 and increase as it gets closer to the gate electrode layer 432.

Referring to FIG. 15, a thickness of the barrier layer 431A may be smaller than a thickness of the insulating layer 431B with respect to the fifth direction DR5 or a seventh direction DR7.

In various embodiments, the insulating layer 431B may include, for example, at least one of silicon oxide, silicon nitride, silicon oxynitride, or a high-k material having a higher dielectric constant than silicon oxide. The high-k material may include, for example, at least one dielectric material selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

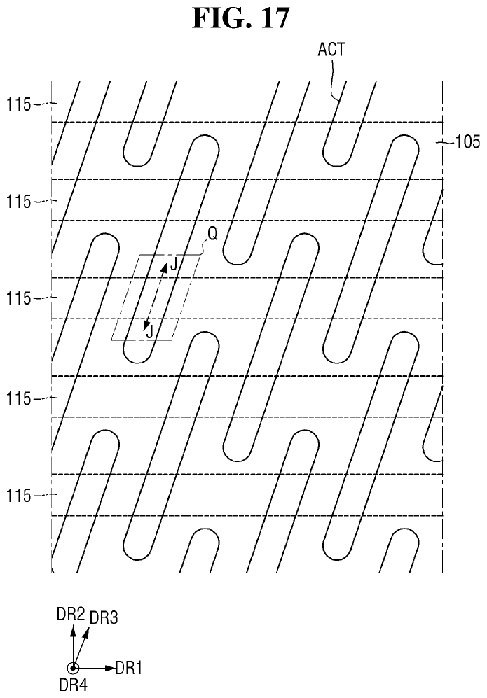

FIGS. 17 to 23 are diagrams illustrating the intermediate steps of a method for fabricating a semiconductor device according to some embodiments. For simplicity of description, redundant parts of the description made with reference to FIGS. 1 to 10 may be recapitulated or omitted.

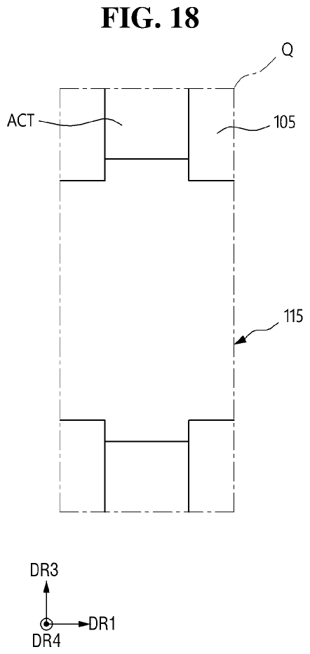

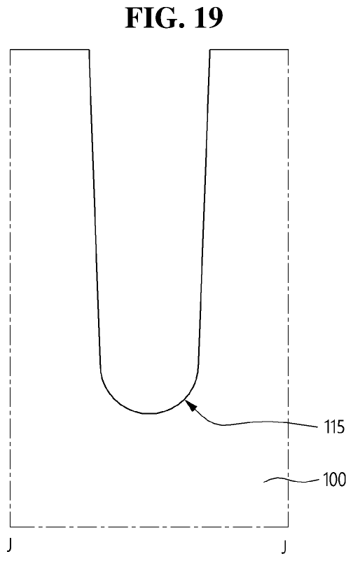

For reference, FIG. 17 is a layout diagram for describing a method for fabricating a semiconductor device according to some embodiments. FIGS. 18, 20 and 22 are enlarged views of part Q of FIG. 17. FIGS. 19, 21 and 23 are cross-sectional views taken along line J-J of FIG. 17.

Referring to FIG. 17, the cell element isolation layer 105 may be formed in the substrate 100, where the cell element isolation layer 105 may have a shallow trench isolation (STI) structure configured to provide element isolation characteristics. The cell element isolation layer 105 may define the cell active area ACT in a memory cell region.

In various embodiments, the cell element isolation layer 105 may include, for example, at least one of a silicon oxide layer, a silicon nitride layer, or a silicon oxynitride layer, but the present disclosure is not limited thereto.

Although the cell element isolation layer 105 is shown to be a single layer, it is only for simplicity of description, and the present disclosure is not limited thereto. The cell element isolation layer 105 may be formed of one insulating layer or may be formed of a plurality of insulating layers.

Referring to FIGS. 18 and 19, the first trench 115 may be formed in the substrate 100 and the cell element isolation layer 105. For example, after forming a mask pattern on the substrate 100, the substrate 100 may be etched using the mask pattern as an etching mask to form the first trench 115. The first trench 115 may extend in the first direction DR1. The first trench 115 may be formed across the cell element isolation layer 105 and the cell active areas ACT where the cell element isolation layer 105 and the cell active areas ACT may be partitioned by the cell element isolation layer 105. The first trench 115 may have a rounded bottom surface.

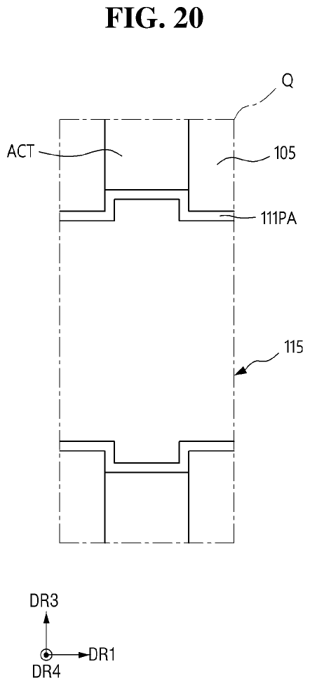

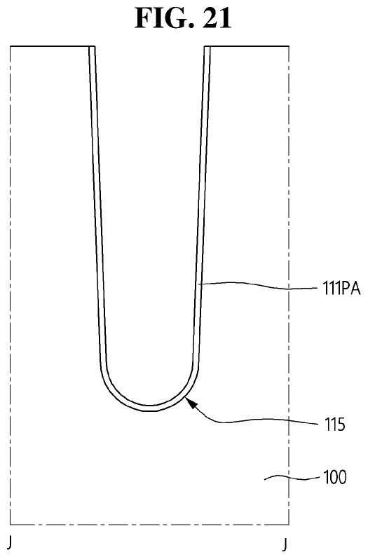

Referring to FIGS. 20 and 21, a pre-barrier layer 111PA including a first material may be formed along the sidewall and the bottom surface of the first trench 115 on the top surfaces of the first trench 115 and the substrate 100.

In various embodiments, the pre-barrier layer 111PA may include at least one of silicon (Si), silicon carbide (SiC), silicon nitride (SiN), silicon carbonitride (SiCN), or silicon oxynitride (SiON).

In various embodiments, the pre-barrier layer 111PA may be formed by a gas phase doping (GPD) method using diisoprophylamino silane (DIPAS), C₂H₄, C₃H₆, or the like, as a source material for containing carbon.

In various embodiments, the pre-barrier layer 111PA may be formed using a SiN layer as a source material for containing nitrogen. Alternatively, the pre-barrier layer 111PA may be formed by a method of nitriding the surface of the cell active area ACT by using plasma.

In various embodiments, the pre-barrier layer 111PA may be formed by a method of additionally depositing a Si layer or additionally depositing a Si-rich oxide layer on the surface of the cell active area ACT.

In various embodiments, the pre-barrier layer 111PA may include, for example, silicon, carbon, nitrogen, or oxygen.

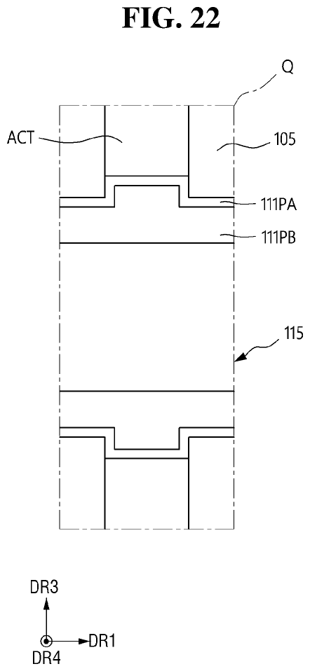

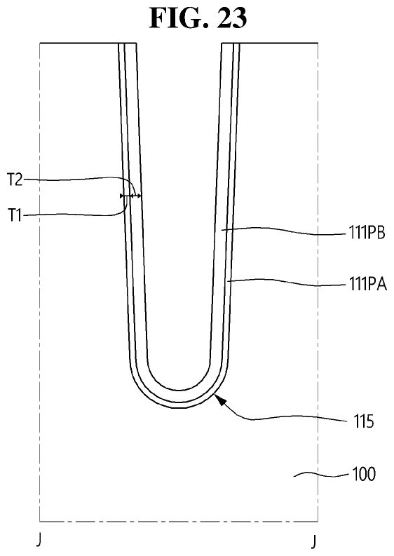

Referring to FIGS. 22 and 23, a pre-insulating layer 111PB including the second material different from the first material may be formed on the sidewall of the pre-barrier layer 111PA.

With respect to the sidewall of the first trench 115, a thickness T1 of the pre-barrier layer 111PA may be less than or equal to half of a thickness T2 of the pre-insulating layer 111PB. For example, the thickness T1 of the pre-barrier layer 111PA may be 20 Å or less, but is not limited thereto.

In various embodiments, the pre-insulating layer 111PB may be formed using an atomic layer deposition (ALD) process or a chemical vapor deposition (CVD) process. The pre-insulating layer 111PB may be formed along the sidewall and bottom surface of the first trench 115. The pre-insulating layer 111PB may include silicon oxide. The pre-insulating layer 111PB may include an interfacial oxide layer formed by oxidizing the pre-barrier layer 111PA on the cell active area ACT. The interfacial oxide layer and the pre-insulating layer 111PB may include the same material, and in this case, an interface between the interfacial oxide layer and the pre-insulating layer 111PB may not be distinguished.

Accordingly, the pre-insulating layer 111PB may include, for example, the second material such as oxygen.

The barrier layer 111A (see e.g., FIG. 8) may be formed from the pre-barrier layer 111PA by a radical oxidation process.

In various embodiments, the radical oxidation process refers to a process of inducing oxygen radicals (O*), which are free radicals, by exciting oxygen gas (O₂) as an oxidation source, and of using an oxidation reaction of oxygen radicals and silicon (Si) or a silicon source.

In various embodiments, when the first material is nitrogen, the radical oxidation process may be performed to substantially oxidize silicon nitride included in the pre-barrier layer 111PA into silicon oxide. The radical oxidation process may be performed by providing radicals of an oxidation source and a reduction source. Oxygen gas may be provided as an oxidation source, and hydrogen gas may be provided as a reduction gas. Oxygen radicals (O*) may be provided on the pre-barrier layer 111PA as an oxidation source, and hydrogen radicals (H*) may be provided as a reduction source that reduces nitrogen included in the nitride. Oxygen radicals (O*) and hydrogen radicals (H*) may break the silicon-nitrogen bonding of the pre-barrier layer 111PA, induce the silicon-oxygen bonding, and induce nitrogen to be removed as a by-product such as nitrogen hydrate. That is, silicon nitride may be oxidized or converted into a silicon oxide layer by a radical oxidation process.

By the radical oxidation process, the barrier layer 111A (see e.g., FIG. 8) may include the first material and the second material. In this case, the concentration of the first material in the insulating layer 111B (see e.g., FIG. 8) may increase as it is closer to the cell active area ACT and decrease as it is closer to the cell gate electrode layer 112. The concentration of the first material in the insulating layer 111B (see e.g., FIG. 8) may be greater in an area adjacent to the cell active area ACT and less in an area adjacent to the cell gate electrode layer 112.

In various embodiments, the concentration of the first material in the first barrier layer 111A may be greater than the concentration of the first material in the first insulating layer 111B. For example, the first insulating layer 111B may not substantially include the first material.

In various embodiments, when the first material is nitrogen, radical oxidation is performed on the pre-barrier layer 111PA including a silicon nitride layer, and as a result of the transmission electron microscope (TEM) analysis of the resulting layer, it may be confirmed that silicon and oxygen are detected, whereas nitrogen is detected in very small amounts. That is, it may be understood that the first barrier layer 111A oxidized by the radical oxidation process substantially includes a silicon oxide layer. Nitrogen components may be detected in a small amount at an interface portion between the cell active area ACT and the first barrier layer 111A.

In various embodiments, the concentration of the second material in the barrier layer 111A (see e.g., FIG. 8) formed through the radical oxidation process may be less than the concentration of the second material in the insulating layer 111B (see e.g., FIG. 8). The concentration of the second material in the cell gate insulating layer 111 may decrease as it is closer to the cell active area ACT and increase as it is closer to the cell gate electrode layer 112. The concentration of the second material in the cell gate insulating layer 111 may be greater in an area adjacent to the cell gate electrode layer 112 than in an area adjacent to the cell active area ACT.

Such oxygen concentration may be measured, for example, by secondary ion mass spectrometry (SIMS), which analyzes the mass of ions (secondary ions) separated from a sample surface when ions (primary ions) having a certain energy are made to collide with the sample surface. In this case, the oxygen concentration may be identified through a profile obtained by measuring the number of oxygen atoms bouncing off from the surface of the sample by using a sputtering process.

In the radical oxidation process, because the reactivity of oxygen radicals (O*) is high, dependence on an Si surface may be small, an oxide layer having a conformal thickness may be obtained, and Si—Si bonding within the oxide layer may be broken, so that the trap charges in the oxide layer may be reduced.

In the radical oxidation process according to some embodiments, the pre-barrier layer 111PA is oxidized, so that oxidation of the lower cell active area ACT may be effectively suppressed. As a result, the cell gate electrode layer 112 in the first trench 115 may be formed to have a more uniform thickness in the third direction DR3. A defect in which the gate electrode is not filled because a gate dielectric layer is excessively formed due to interfacial oxide formed in the silicon of the active area may be prevented.

In various embodiments, silicon oxidation or silicon loss in the lower cell active area ACT shielded by the first barrier layer 111A may be effectively suppressed. Because loss or oxidation of silicon in the cell active area ACT may be effectively suppressed, a decrease in channel width may be suppressed and a decrease in channel resistance may be induced.

In various embodiments, a conductive material may be deposited on the pre-insulating layer 111PB, where the conductive material may fill the first trench 115. Deposition of the conductive material may be performed using a chemical vapor deposition (CVD) process or the like. The conductive material may include at least one of Mo, W, TiN, and/or Ru.

Accordingly, the cell gate electrode layer 112 as illustrated in FIG. 8 may be formed. Thereafter, the cell gate structure 110 may be formed through a planarization process on the gate electrode layer 112. The cell gate structure 110 may include the cell gate trench 115, the cell gate insulating layer 111, the cell gate electrode layer 112, the cell gate capping conductive layer 113, and the cell gate capping layer 114. The cell gate electrode layer 112 may correspond to the word line WL.

Subsequently, the bit line structure 140ST extending in the second direction DR2 may be formed on the substrate 100. The bit line structure 140ST may include the cell conductive line 140, the cell line capping layer 144, and the bit line spacer 150.

In various embodiments, the storage contact 120, the storage pad 160, and the information storage unit 190 may be formed on the second portion 103b of the cell active area ACT. The information storage unit 190 may include the lower electrode 191, the capacitor dielectric layer 192, and the upper electrode 193.

In concluding the detailed description, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed is:

1. A semiconductor device comprising:
a substrate comprising an element isolation layer defining a plurality of active areas; and
a plurality of gate structures intersecting the plurality of active areas,
wherein each of the plurality of gate structures comprises:
a gate insulating layer comprising a first region containing a first material and a second region containing a second material different from the first material on the active area; and
a gate electrode layer on the gate insulating layer,
wherein a concentration of the second material in the first region is less than a concentration of the second material in the second region, and
a thickness of the gate insulating layer in the first region is less than the thickness of the gate insulating layer in the second region.

2. The semiconductor device of claim 1, wherein a concentration of the first material in the first region is greater than a concentration of the first material in the second region.

3. The semiconductor device of claim 1, wherein a concentration of the second material in the gate insulating layer is greater in an area adjacent to the gate electrode layer than in an area adjacent to the active area.

4. The semiconductor device of claim 1, wherein a concentration of the first material in the gate insulating layer is smaller in an area adjacent to the gate electrode layer than in an area adjacent to the active area.

5. The semiconductor device of claim 1, wherein the first material contains at least one of silicon, carbon, nitrogen, or oxygen, and
the second material contains oxygen.

6. The semiconductor device of claim 1, wherein each of the gate structures further comprises a capping layer on a top surface of the gate electrode layer and a sidewall of the second region.

7. The semiconductor device of claim 6, wherein a bottom surface of the capping layer is not in contact with a top surface of the first region and a top surface of the second region.

8. The semiconductor device of claim 1, further comprising nanosheets surrounded by each of the gate structures.

9. A semiconductor device comprising:
a substrate comprising an element isolation layer defining a cell region and a peripheral region around the cell region, and defining first active areas; and
cell gate structures formed in a first trench on the substrate and intersecting the first active areas, in the cell region,
wherein each of the cell gate structures comprises:
a first barrier layer comprising a first region containing a first material and a second region containing a second material, wherein the first barrier layer is in the first trench and extends along a sidewall and a bottom surface of the first trench;
a cell gate insulating layer containing the second material on a sidewall of the first barrier layer, and extending along the sidewall and the bottom surface of the first trench;
a cell gate electrode layer on a sidewall of the cell gate insulating layer that fills the first trench; and
a capping layer on a top surface of the cell gate electrode layer and a sidewall of the cell gate insulating layer,
wherein a concentration of the second material in the first barrier layer is smaller than a concentration of the second material in the cell gate insulating layer.

10. The semiconductor device of claim 9, wherein with respect to a sidewall of the first trench, a thickness of the first barrier layer is less than a thickness of the cell gate insulating layer.

11. The semiconductor device of claim 9, wherein a concentration of the second material in the first barrier layer decreases as it gets closer to the first active area and increases as it gets closer to the cell gate electrode layer.

12. The semiconductor device of claim 9, wherein the cell gate insulating layer does not contain the first material.

13. The semiconductor device of claim 9, wherein the first material contains at least one of silicon, carbon, nitrogen, or oxygen, and
the second material contains oxygen.

14. The semiconductor device of claim 9, further comprising a plurality of peripheral gate structures formed on the substrate and intersecting second active areas, in the peripheral region,
wherein each of the peripheral gate structures comprises:
a second barrier layer comprising a third region containing the first material and a fourth region containing the second material, on the second active area;
a peripheral gate insulating layer containing the second material, on the second barrier layer, and
a peripheral gate electrode layer disposed on the peripheral gate insulating layer.

15. The semiconductor device of claim 14, wherein a concentration of the second material in the second barrier layer is less than a concentration of the second material in the peripheral gate insulating layer.

16. The semiconductor device of claim 14, wherein a thickness of the second barrier layer is less than a thickness of the peripheral gate insulating layer.

17. The semiconductor device of claim 9, further comprising:
first and second source/drain regions in the first active areas;
bit line structures on the substrate, and connected to the first source/drain region; and
information storage units on the substrate, and connected to the second source/drain region.

18. A method for fabricating a semiconductor device, comprising:
forming an element isolation layer defining a plurality of active areas on a substrate;
forming a first trench intersecting at least a portion of the plurality of active areas in the substrate;
forming a barrier layer containing a first material along a sidewall and a bottom surface of the first trench;
forming a gate insulating layer containing a second material different from the first material, on a sidewall of the barrier layer; and
forming a gate electrode layer on a sidewall of the gate insulating layer and filling an inside of the first trench,
wherein with respect to the sidewall of the first trench, a thickness of the barrier layer is less than or equal to half of a thickness of the gate insulating layer.

19. The method of claim 18, wherein a concentration of the first material in the barrier layer is greater in an area adjacent to the active area than in the gate electrode layer, and
a concentration of the second material in the barrier layer is greater in an area adjacent to the gate electrode layer than in the active area.

20. The method of claim 18, wherein the barrier layer contains at least one of silicon, silicon carbide, silicon nitride, silicon carbonitride, or silicon oxynitride, and
the gate insulating layer contains silicon oxide.
